(19) United States
(12) Patent Application Publication
(10) Pub. No.: US 2026/0123130 A1
(43) Pub. Date: Apr. 30, 2026

(54) PACKAGE STRUCTURE

(71) Applicant: Lextar Electronics Corporation, Hsinchu City (TW)

(72) Inventors: Shiou-Yi KUO, Hsinchu City (TW); Bo-Yu CHEN, Hsinchu (TW); Chin-Hung LO, Hsinchu City (TW)

(21) Appl. No.: 19/371,554

(22) Filed: Oct. 28, 2025

(30) Foreign Application Priority Data
Oct. 28, 2024 (TW) 113140982

(51) Int. Cl. H10H 29/24; H01L 23/00; H01L 23/31; H01L 23/498; H01L 25/16; H10H 29/85; H10H 29/852

(52) U.S. Cl. CPC H10H 29/24; H10H 29/8508; H10H 29/852; H10W 70/635; H10W 74/114; H10W 90/00; H10W 90/794

(57) ABSTRACT

A packaging structure is provided. The packaging structure includes a first dielectric layer, a redistribution structure, a plurality of light-emitting elements, an integrated circuit element, and a cover layer. The first dielectric layer has a top surface and a side surface. The redistribution structure is disposed in the first dielectric layer. The plurality of light-emitting elements is disposed on the first dielectric layer. The integrated circuit element is disposed on the first dielectric layer and adjacent to the plurality of light-emitting elements. The cover layer is disposed on the plurality of light-emitting elements and the integrated circuit element. The cover layer surrounds the plurality of light-emitting elements and the integrated circuit element. The cover layer is in direct contact with the top surface and the side surface of the first dielectric layer.

### CROSS REFERENCE TO RELATED APPLICATIONS

This application claims priority of Taiwan patent application No. 113140982, filed on Oct. 28, 2024, the entirety of which is incorporated by reference herein.

### TECHNICAL FIELD

The present disclosure relates to a packaging structure and a display device including the same, and, in particular, it relates to an improved packaging structure and a display device including the same.

### BACKGROUND

As the size of existing packaging structures is miniaturized, problems such as poor light-emitting efficiency, insufficient bonding reliability, and electrical failure often arise. As a result, they are limited in applications that require high light-emitting efficiency and high brightness.

Therefore, although existing packaging structures and display devices including the same have gradually met their intended uses, they still do not fully meet requirements in all respects. Therefore, there are still some problems to be overcome regarding packaging structures and display devices including the same.

### BRIEF SUMMARY

An embodiment of the present disclosure provides a packaging structure. The packaging structure includes a first dielectric layer, a redistribution structure, a plurality of light-emitting elements, an integrated circuit element, and a cover layer. The first dielectric layer has a top surface and a side surface. The redistribution structure is disposed in the first dielectric layer. The plurality of light-emitting elements is disposed on the first dielectric layer. The integrated circuit element is disposed on the first dielectric layer and adjacent to the plurality of light-emitting elements. The cover layer is disposed on the plurality of light-emitting elements and the integrated circuit element. The cover layer surrounds the plurality of light-emitting elements and the integrated circuit element. The cover layer is in direct contact with the top surface and the side surface of the first dielectric layer.

An embodiment of the present disclosure provides a display device. The display device includes the packaging structure.

The packaging structure and the display device including the same of the present disclosure may be applied in various types of electronic apparatuses. In order to make the features and advantages of some embodiments of the present disclosure more easily understood, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1A is a schematic cross-sectional view of a packaging structure according to some embodiments of the present disclosure.

FIG. 1B is a schematic cross-sectional view of a region of a packaging structure according to some embodiments of the present disclosure.

FIG. 2 is a schematic top view of a packaging structure according to some embodiments of the present disclosure.

FIG. 3A to FIG. 3M are schematic cross-sectional views of different stages of a method for forming a packaging structure according to some embodiments of the present disclosure.

FIG. 4 and FIG. 5 are scanning electron microscope (SEM) analysis diagrams of a packaging structure according to some embodiments of the present disclosure, respectively.

FIG. 6 and FIG. 7 are scanning electron microscope (SEM) analysis diagrams of a region of a packaging structure according to some embodiments of the present disclosure, respectively.

FIG. 8 is a schematic cross-sectional view of a display device according to some embodiments of the present disclosure.

FIG. 9 is a schematic top view of a spliced display device according to some embodiments of the present disclosure.

### DETAILED DESCRIPTION

Packaging structures and display devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure. Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact. In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” or “a first value ˜ a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1, the Y-axis direction is the second direction D2, and the Z-axis direction is the third direction D3 (thickness/depth direction). In some embodiments, the schematic top views described herein are schematic views of the XY plane. In some embodiments, the third direction D3 may be a normal direction of a first dielectric layer, a cover layer, or a packaging layer.

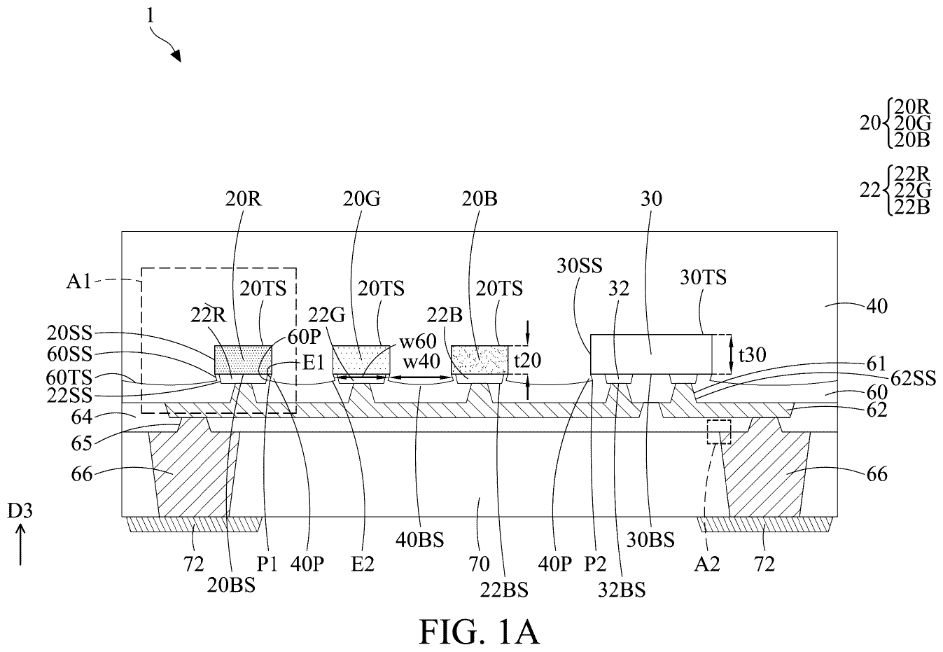

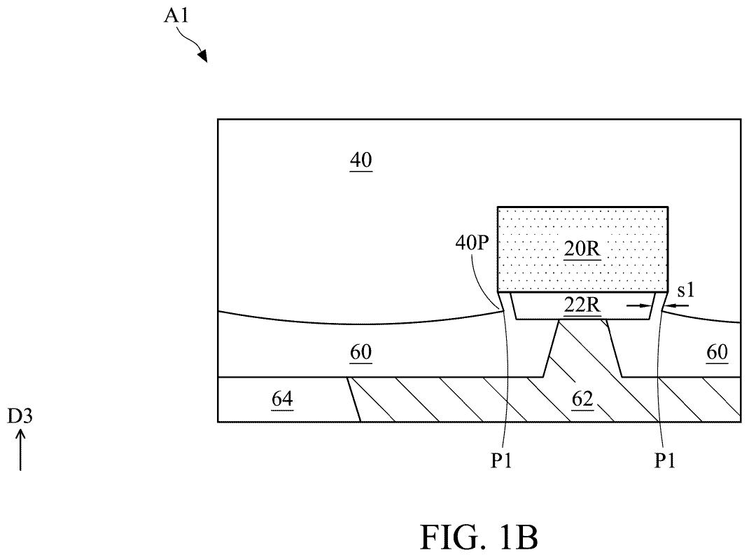

Referring to FIG. 1A, it is a cross-sectional schematic view of a packaging structure according to some embodiments of the present disclosure. As shown in FIG. 1A, in some embodiments, the packaging structure 1 may include a first dielectric layer 60, a redistribution structure 62, a plurality of light-emitting elements 20, an integrated circuit element 30, and a cover layer 40. In some embodiments, the first dielectric layer 60 may include an oxide such as silicon oxide, a nitride such as silicon nitride, an oxynitride such as silicon oxynitride, a polymer, a resin, the like, or a combination thereof, but the present disclosure is not limited thereto. In some embodiments, the first dielectric layer 60 may be or may include epoxy, polyimide (PI), polybenzoxazole (PBO), or silicone. In some embodiments, the cover layer 40 may be silicone, epoxy, other suitable materials, or a combination thereof, but the present disclosure is not limited thereto.

As shown in FIG. 1A, in some embodiments, a redistribution structure 62 may be disposed in a first opening 61 of a first dielectric layer 60 to provide a current path in the first dielectric layer 60. In some embodiments, the redistribution structure 62 may include a conductive material. In some embodiments, the conductive material may include a metal, a conductive metal oxide, a conductive metal nitride, the like, or a combination thereof, but the present disclosure is not limited thereto. For example, the metal may include tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), alloys thereof or compounds thereof, or a combination thereof, but the present disclosure is not limited thereto. For example, the conductive metal oxide may be a transparent conductive oxide (TCO). For example, the transparent conductive oxide may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), the like, or a combination thereof, but the present disclosure is not limited thereto. For example, the conductive metal nitride may include TiN, WN, TaN, the like, or a combination thereof, but the present disclosure is not limited thereto.

As shown in FIG. 1A, in some embodiments, the plurality of light-emitting elements 20 may be disposed on the first dielectric layer 60. In some embodiments, the plurality of light-emitting elements 20 may be disposed at intervals, such as in an array. In some embodiments, the light-emitting element 20 may be a light-emitting diode (LED), a mini light-emitting diode (mini LED), a micro light-emitting diode (micro LED), the like, or a combination thereof, but the present disclosure is not limited thereto. In some embodiments, the light-emitting element 20 may emit red light, green light, blue light, ultraviolet light (UV light), or other light with suitable wavelength. In some embodiments, the number of light-emitting elements 20 in the packaging structure 1 may be 1 to 100. For ease of illustration, three light-emitting elements 20 are shown in FIG. 1A, but the present disclosure is not limited thereto.

In some embodiments, the light-emitting elements 20 may include a red light-emitting element 20R emitting red light, a green light-emitting element 20G emitting green light, and a blue light-emitting element 20B emitting blue light. In some embodiments, the green light-emitting element 20G may be disposed between the red light-emitting element 20R and the blue light-emitting element 20B. In some embodiments, the light-emitting element 20 may include a substrate (not shown), a semiconductor stack (not shown), an insulating layer (not shown), a functional layer such as a reflective layer (not shown), and a bonding pad 22. In some embodiments, the semiconductor stack may include a first semiconductor layer (not shown), a light-emitting layer (not shown), and a second semiconductor layer (not shown) stacked in sequence, and the first semiconductor layer and the second semiconductor layer have different conductivity types. In some embodiments, the bonding pad 22 may be electrically connected to the semiconductor stack. In some embodiments, the bonding pad 22 may include the aforementioned conductive material. In some embodiments, the light-emitting element 20 may be electrically connected to the redistribution structure 62 via the bonding pad 22. In some embodiments, the light-emitting element 20 may be a flip chip light-emitting element.

As shown in FIG. 1A, in some embodiments, the integrated circuit element 30 may be disposed on the first dielectric layer 60, and the integrated circuit element 30 may be disposed adjacent to the plurality of light-emitting elements 20. In some embodiments, the integrated circuit element 30 may be a micro integrated circuit (uIC) chip. In some embodiments, the integrated circuit element 30 may include a bonding pad 32. In some embodiments, the bonding pad 32 may include the aforementioned conductive material. In some embodiments, the integrated circuit element 30 may be electrically connected to the redistribution structure 62 via the bonding pad 32. In some embodiments, the redistribution structure 62 may electrically connect the plurality of light-emitting elements 20 and the integrated circuit element 30. Accordingly, the integrated circuit element 30 may be used to control the plurality of light-emitting elements 20 in the packaging structure 1.

As shown in FIG. 1A, in some embodiments, in the normal direction (the third direction D3) of the first dielectric layer 60, a top surface 30TS of the integrated circuit element 30 may be higher than the top surface 20TS of the light-emitting element 20. In some embodiments, in the third direction D3, the light-emitting element 20 may have a first thickness t20. In some embodiments, in the third direction D3, the integrated circuit element 30 may have a second thickness t30. In some embodiments, the second thickness t30 may be greater than the first thickness t20. In some embodiments, the difference between the second thickness t30 and the first thickness t20 (the second thickness t30−the first thickness t20) may be less than or equal to 10 μm. For example, the difference between the second thickness t30 and the first thickness t20 may be 10 μm, 9 μm, 8 μm, 7 μm, 6 μm, 5 μm, 4 μm, 3 μm, 2 μm, 1 μm, or less, or any value or any range of values between the aforementioned values, but the present disclosure is not limited thereto.

As shown in FIG. 1A, in some embodiments, in the third direction D3, the height difference between a bottom surface 22BS of the bonding pad 22 of the light-emitting element 20 and a bottom surface 32BS of the bonding pad 32 of the integrated circuit element 30 may be less than or equal to 10 μm. For example, the height difference between the bottom surface 22BS of the bonding pad 22 and the bottom surface 32BS of the bonding pad 32 may be 10 μm, 9 μm, 8 μm, 7 μm, 6 μm, 5 μm, 4 μm, 3 μm, 2 μm, 1 μm, or less, or any value or any range of values between the aforementioned values, but the present disclosure is not limited thereto. Accordingly, the plurality of light-emitting elements 20 and the integrated circuit element 30 may be substantially disposed on the same plane.

As shown in FIG. 1A, in some embodiments, the cover layer 40 may be disposed on the plurality of light-emitting elements 20 and the integrated circuit element 30, and may be in direct contact with the plurality of light-emitting elements 20 and the integrated circuit element 30. In some embodiments, the cover layer 40 may surround each of the plurality of light-emitting elements 20, and may surround the integrated circuit element 30. In some embodiments, the cover layer 40 may cover a side surface 20SS and the top surface 20TS of the light-emitting element 20, and the cover layer 40 may cover a side surface 30SS and the top surface 30TS of the integrated circuit element 30. In some embodiments, the top surface 20TS of the plurality of light-emitting elements 20 may be the light-emitting surface of the light-emitting element 20, and the cover layer 40 may be in direct contact with the top surface 20TS of the plurality of light-emitting elements 20. In other words, the cover layer 40 may be in direct contact with the light-emitting surface of the plurality of light-emitting elements 20. Accordingly, the cover layer 40 may effectively protect the light-emitting surface of the light-emitting element 20.

In some embodiments, the cover layer 40 may be in direct contact with a top surface 60TS and a side surface 60SS of the first dielectric layer 60. Accordingly, since the cover layer 40 not only contacts the top surface 60TS of the first dielectric layer 60 but also contacts the side surface 60SS of the first dielectric layer 60, the bonding reliability between the cover layer 40 and the first dielectric layer 60 may be improved, and the packaging reliability of the cover layer 40 covering the light-emitting element 20 and the integrated circuit element 30 may be improved. In some embodiments, the cover layer 40 may continuously surround the side surface 20SS of the light-emitting element 20. In some embodiments, the cover layer 40 may continuously surround the side surfaces of the red light-emitting element 20R, the green light-emitting element 20G, and the blue light-emitting element 20B. In some embodiments, a portion of the cover layer 40 between adjacent light-emitting elements 20 may have a width w40, and the width w40 gradually increases along the direction toward the first dielectric layer 60 (the direction opposite to the third direction D3) and then gradually decreases. In contrast, a portion (for example, a top portion) of the first dielectric layer 60 may have a width w60, and the width w60 gradually increases along a direction (the third direction D3) toward the cover layer 40.

As shown in FIG. 1A, in some embodiments, the cover layer 40 may surround the redistribution structure 62. In some embodiments, the cover layer 40 may cover a side surface 62SS of the redistribution structure 62. In some embodiments, the cover layer 40 may have a protruding portion 40P protruding toward the redistribution structure 62. In some embodiments, the protruding portion 40P of the cover layer 40 may cover a bottom surface 20BS of the light-emitting element 20 and a bottom surface 30BS of the integrated circuit element 30. In the third direction D3, the protruding portion 40P of the cover layer 40 may be located below the light-emitting element 20 and the integrated circuit element 30. In other words, at least a portion of the cover layer 40 may be between the light-emitting element 20 and the first dielectric layer 60. At least a portion of the cover layer 40 may be between the integrated circuit element 30 and the first dielectric layer 60.

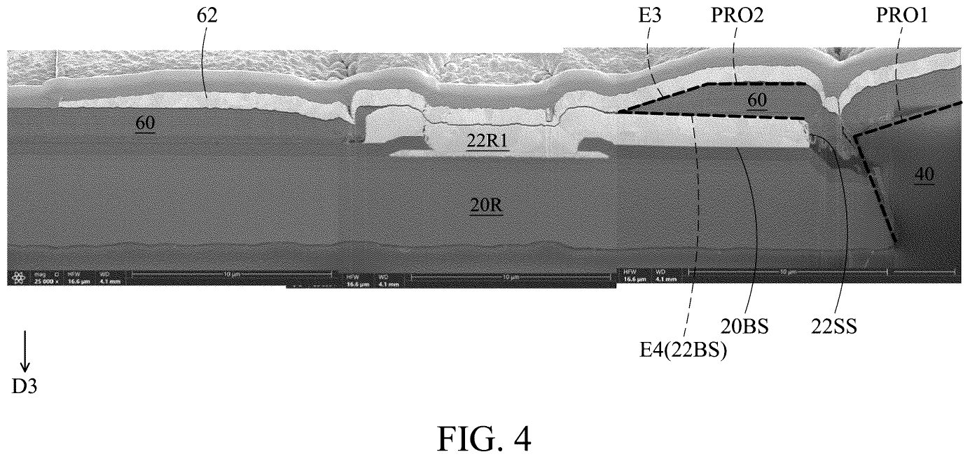

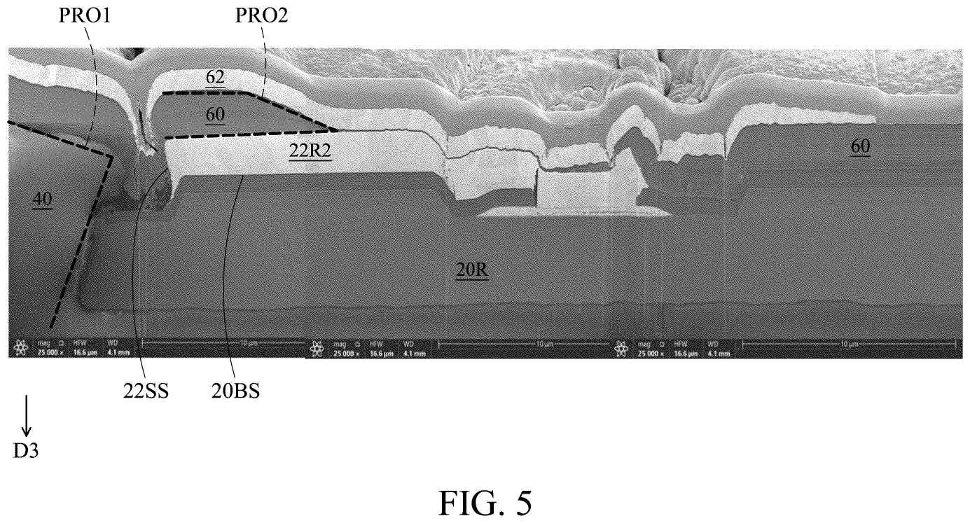

As shown in FIG. 1A, in some embodiments, in a cross-sectional view, the protruding portion 40P of the cover layer 40 may have a triangular-like profile (for example, a triangular-like profile PRO1 shown in subsequent FIG. 4 and FIG. 5). In some embodiments, in the third direction D3, a vertex P1 of the triangular-like profile of the protruding portion 40P may be located below the bottom surface 20BS of the plurality of light-emitting elements 20. In some embodiments, in the third direction D3, the vertex P2 of the triangular-like profile of the protruding portion 40P may be located below the bottom surface 30BS of the integrated circuit element 30. In some embodiments, the triangular-like profile of the protruding portion 40P of the cover layer 40 may have an acute angle adjacent to the first dielectric layer 60. In some embodiments, a side edge E1 of the protruding portion 40P of the cover layer 40 may form an angle with a bottom edge E2 of the protruding portion 40P of the cover layer 40, and the angle may be greater than 0 degrees and less than 90 degrees. For example, the angle of the protruding portion 40P of the cover layer 40 may be 1 degree, 10 degrees, 15 degrees, 20 degrees, 25 degrees, 30 degrees, 35 degrees, 40 degrees, 45 degrees, 50 degrees, 55 degrees, 60 degrees, 75 degrees, 89 degrees, or any value or any range of values between the aforementioned values, but the present disclosure is not limited thereto. Accordingly, by providing the cover layer 40 having the protruding portion 40P, the bonding reliability between the cover layer 40 and the first dielectric layer 60 may be improved, and the packaging reliability of the cover layer 40 covering the light-emitting element 20 and the integrated circuit element 30 may be improved.

As shown in FIG. 1A, in some embodiments, the first dielectric layer 60 may have a neck portion 60P, and the neck portion 60P may surround the redistribution structure 62. In some embodiments, the neck portion 60P of the first dielectric layer 60 may correspond to the protruding portion 40P of the cover layer 40. In some embodiments, the neck portion 60P of the first dielectric layer 60 may be in direct contact with the protruding portion 40P of the cover layer 40. Accordingly, by providing the cover layer 40 having the protruding portion 40P and the first dielectric layer 60 having the neck portion 60P, a structure similar to a tenon may be formed. Therefore, the bonding reliability between the cover layer 40 and the first dielectric layer 60 may be improved, and the packaging reliability of the cover layer 40 and the first dielectric layer 60 together covering the light-emitting element 20 and the integrated circuit element 30 may be improved.

As shown in FIG. 1A, in some embodiments, the top surface 60TS of the first dielectric layer 60 may be not a flat surface, and a bottom surface 40BS of the cover layer 40 may be not a flat surface. In some embodiments, the top surface 60TS of the first dielectric layer 60 and the bottom surface 40BS of the cover layer 40 may have shapes corresponding to each other, for example, shapes corresponding to concave and convex shapes. In some embodiments, the bottom surface 40BS of the cover layer 40 between adjacent light-emitting elements 20 among the plurality of light-emitting elements 20 may protrude toward the first dielectric layer 60 along the direction D3 and may have a protruding bottom surface 40BS. In some embodiments, the bottom surface 40BS of the cover layer 40 between the light-emitting element 20 located closest to the integrated circuit element 30 among the plurality of light-emitting elements 20 may protrude toward the first dielectric layer 60 along the third direction D3. In some embodiments, the first dielectric layer 60 may have a concave top surface 60TS that corresponds to the bottom surface 40BS of the cover layer 40. Accordingly, by providing the cover layer 40 and the first dielectric layer 60 with corresponding surface shapes, the bonding reliability between the cover layer 40 and the first dielectric layer 60 may be improved, and the packaging reliability of the cover layer 40 and the first dielectric layer 60 together covering the light-emitting element 20 and the integrated circuit element 30 may be improved.

As shown in FIG. 1A, in some embodiments, the packaging structure 1 may further include a second dielectric layer 64. In some embodiments, the second dielectric layer 64 may be disposed on the redistribution structure 62, and the redistribution structure 62 may be between the first dielectric layer 60 and the second dielectric layer 64. In some embodiments, the first dielectric layer 60 and the second dielectric layer 64 may together surround the redistribution structure 62. In some embodiments, the material of the second dielectric layer 64 may be the same as or different from the material of the first dielectric layer 60.

As shown in FIG. 1A, in some embodiments, the packaging structure 1 may further include a metal pillar 66, a packaging layer 70, and a bonding pad 72. In some embodiments, the packaging layer 70 may be disposed on the second dielectric layer 64, and the second dielectric layer 64 may be between the redistribution structure 62 and the packaging layer 70. In some embodiments, the second dielectric layer 64 may be between the first dielectric layer 60 and the packaging layer 70. In some embodiments, the packaging layer 70 may be in direct contact with the second dielectric layer 64. In some embodiments, the packaging layer 70 may include a molding material 73. For example, the molding material 73 may include epoxy, silicone, the like, or a combination thereof, but the present disclosure is not limited thereto.

As shown in FIG. 1A, in some embodiments, the metal pillar 66 may be disposed in the packaging layer 70. In some embodiments, the metal pillar 66 may be disposed in a second opening 65 of the second dielectric layer 64. In some embodiments, the metal pillar 66 may pass through the packaging layer 70 and the second dielectric layer 64 and be electrically connected to the redistribution structure 62. In some embodiments, the metal pillar 66 may include the aforementioned conductive material.

As shown in FIG. 1A, in some embodiments, the bonding pad 72 may be disposed on the packaging layer 70. In some embodiments, the metal pillar 66 may be between the bonding pad 72 and the redistribution structure 62. In some embodiments, the bonding pad 72 may be electrically connected to the metal pillar 66. In some embodiments, the bonding pad 72 may include the aforementioned conductive material. In some embodiments, the bonding pad 72 may be electrically connected to an external circuit outside the packaging structure 1. Therefore, an external current may be applied to the light-emitting element 20 via the bonding pad 72, the metal pillar 66, the redistribution structure 62, and the bonding pad 22. In some embodiments, the external current may be applied to the integrated circuit element 30 via the bonding pad 72, the metal pillar 66, the redistribution structure 62, and the bonding pad 32.

Accordingly, the redistribution structure 62, the metal pillar 66, and the bonding pad 72 in the packaging structure 1 may be used together as the extended electrodes of the light-emitting element 20 and the integrated circuit element 30 to improve the light-emitting efficiency, improve the bonding reliability, and/or avoid electrical failure. In detail, the alignment during bonding processes such as fusion bonding is difficult, and leads to reduced light-emitting efficiency of the light-emitting element 20, insufficient bonding reliability, and even electrical failure of the light-emitting element 20 or the integrated circuit element 30. In addition, since bonding processes such as fusion bonding require precise alignment, the process margin (window) of the formation process is also limited. Therefore, based on the present disclosure, the use of the redistribution structure 62, the metal pillar 66, and the bonding pad 72 as the extended electrode of the packaging structure 1 may effectively avoid the above-mentioned problems existing in the bonding pad-to-bonding pad (site-to-site) bonding structure.

Referring to FIG. 1B, it is a schematic cross-sectional view of the first region A1 according to the packaging structure 1 of some embodiments of the present disclosure. In some embodiments, the cover layer 40 may cover the periphery of the light-emitting element 20 (for example, the red light-emitting element 20R). In some embodiments, a portion of the cover layer 40 (for example, the protruding portion 40P) may be in a triangular-like shape below the light-emitting element 20. In some embodiments, the protruding portion 40P does not directly contact the light-emitting element 20. In some embodiments, the distance between the vertex P1 of the protruding portion 40P and the bonding pad 22 of the light-emitting element 20 (for example, the bonding pad 22R of the red light-emitting element 20R) may be less than 3 μm. For example, the distance between the vertex P1 of the protruding portion 40P and the bonding pad 22 of the light-emitting element 20 may be 2.99 μm, 2.5 μm, 2 μm, 1.5 μm, 1 μm, 0.5 μm, 0.1 μm, or less, or any value or any range of values between the aforementioned values, but the present disclosure is not limited thereto.

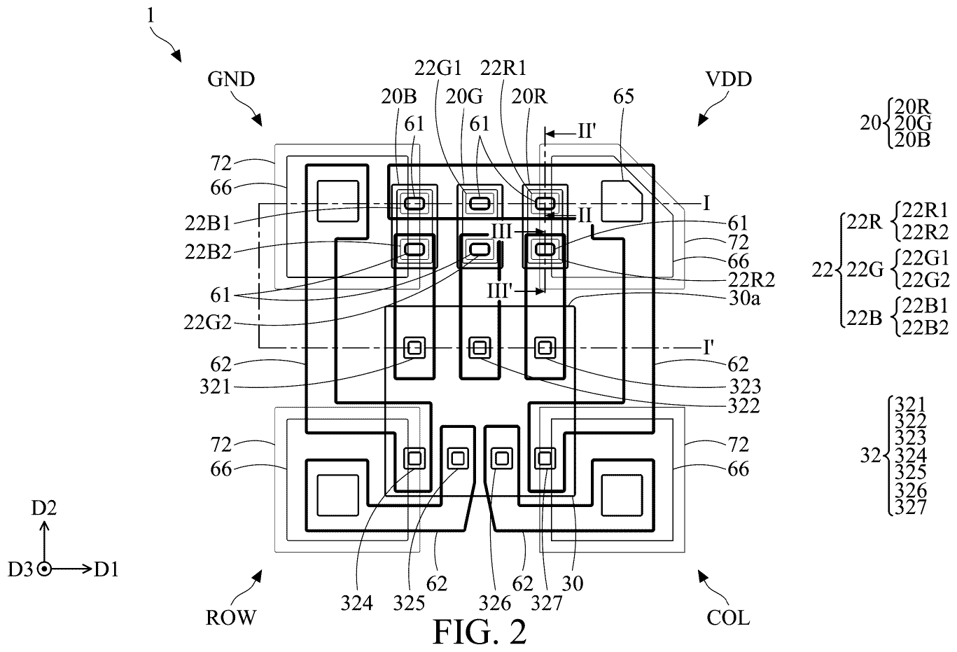

Referring to FIG. 2, it is a schematic top view of a packaging structure 1 according to some embodiments of the present disclosure. FIG. 1A shows a schematic cross-sectional view taken along line segment I-I′ of FIG. 2. As shown in FIG. 2, in some embodiments, the plurality of light-emitting elements 20 may be arranged along a side 30a of the integrated circuit element 30. In other words, three light-emitting elements 20 may be disposed on the same side 30a of the integrated circuit element 30.

As shown in FIG. 2, in some embodiments, the bonding pad 22 of the light-emitting element 20 may be electrically connected to the bonding pad 32 of the integrated circuit element 30 through the redistribution structure 62. In some embodiments, the bonding pad 22B1 of the blue light-emitting element 20B, the bonding pad 22G1 of the green light-emitting element 20G, and the bonding pad 22R1 of the red light-emitting element 20R may be used as positive electrodes and are electrically connected to the bonding pad 327 of the integrated circuit element 30 in common. In some embodiments, the bonding pad 327 of the integrated circuit element 30 may be electrically connected to the voltage source VDD. In some embodiments, the bonding pad 22B2 of the blue light-emitting element 20B, the bonding pad 22G2 of the green light-emitting element 20G, and the bonding pad 22R2 of the red light-emitting element 20R may be used as negative electrodes and are electrically connected to the bonding pads 321, 322, and 323 of the integrated circuit element 30 in sequence. In some embodiments, the bonding pad 324 of the integrated circuit element 30 may be electrically connected to the ground terminal GND. In some embodiments, the bonding pads 325 and 326 of the integrated circuit element 30 may be electrically connected to the row line ROW and the column line COL in sequence, respectively.

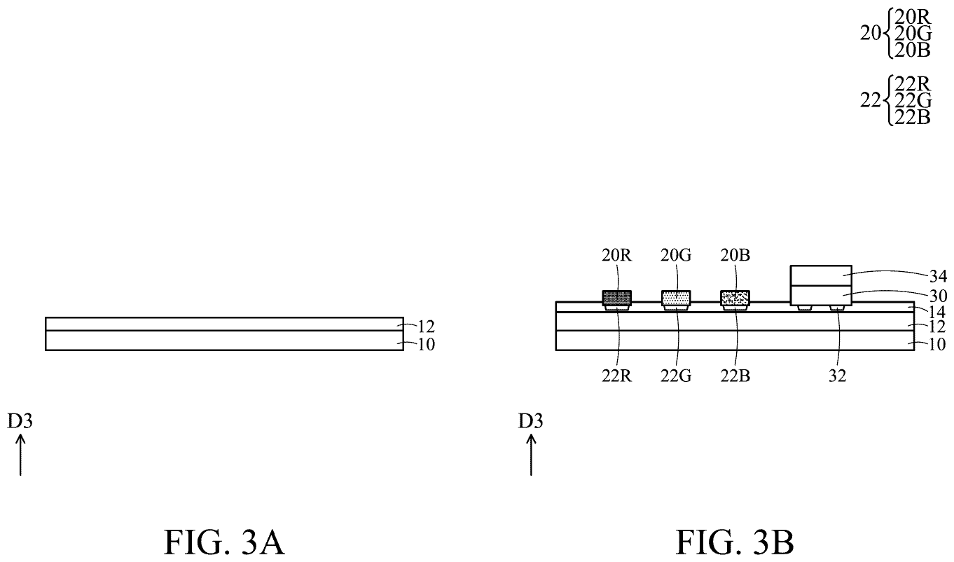

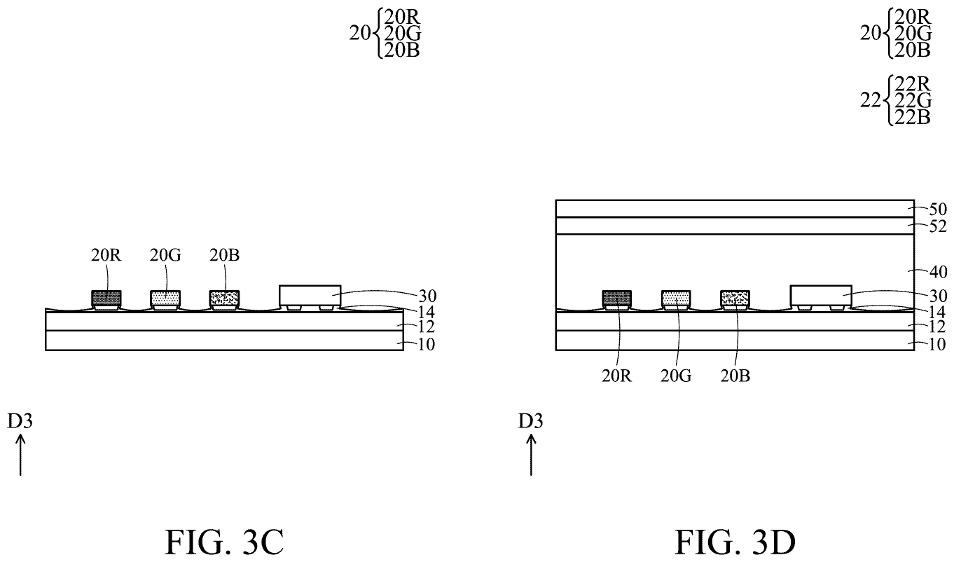

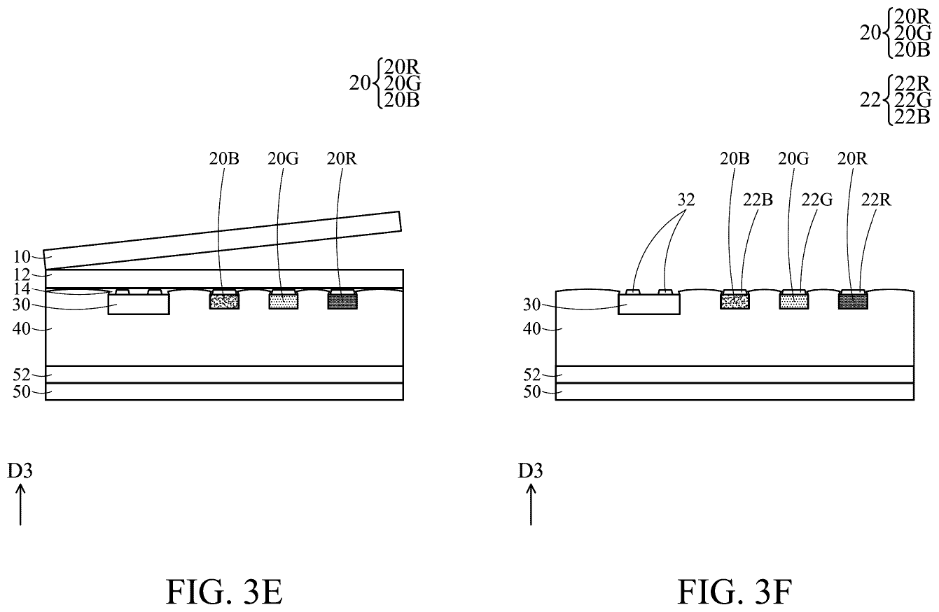

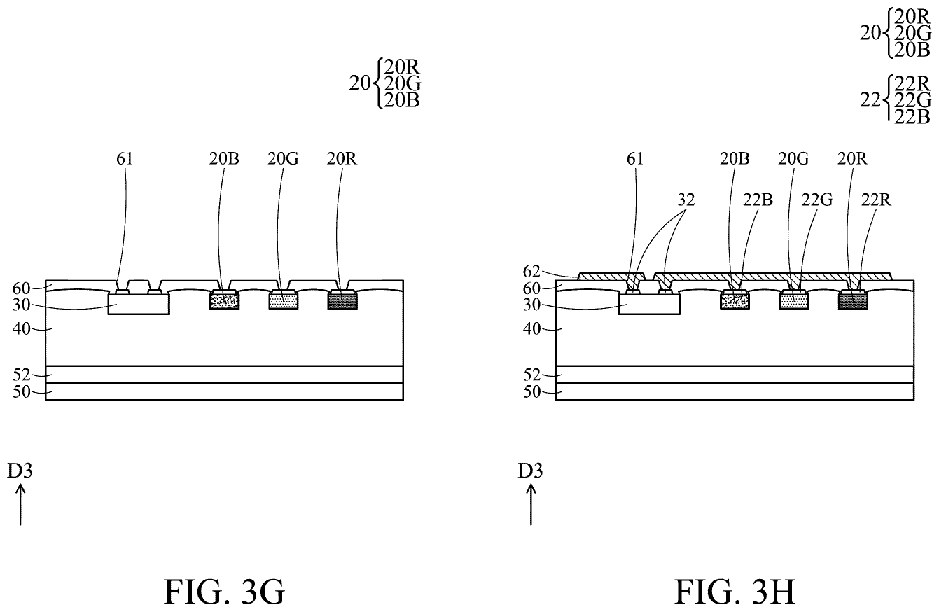

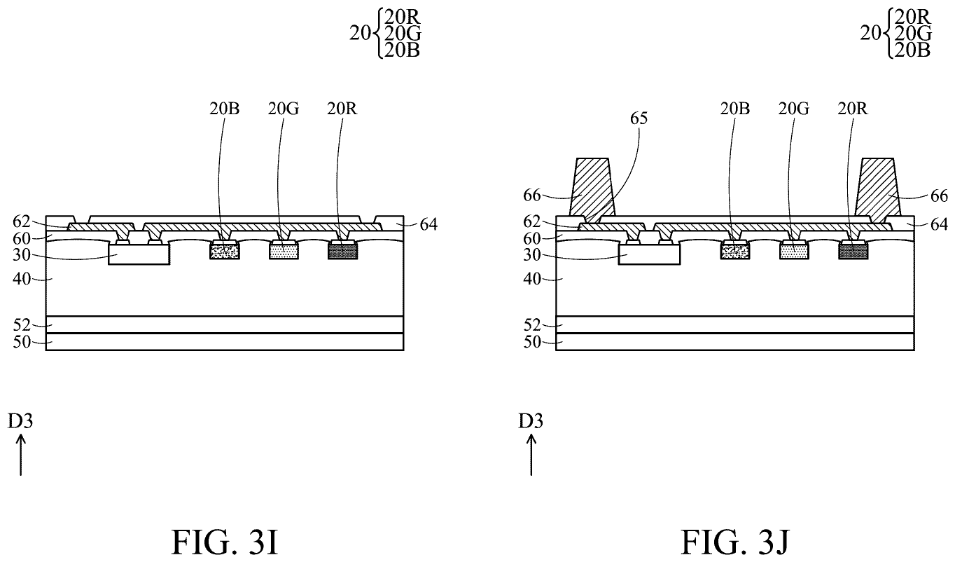

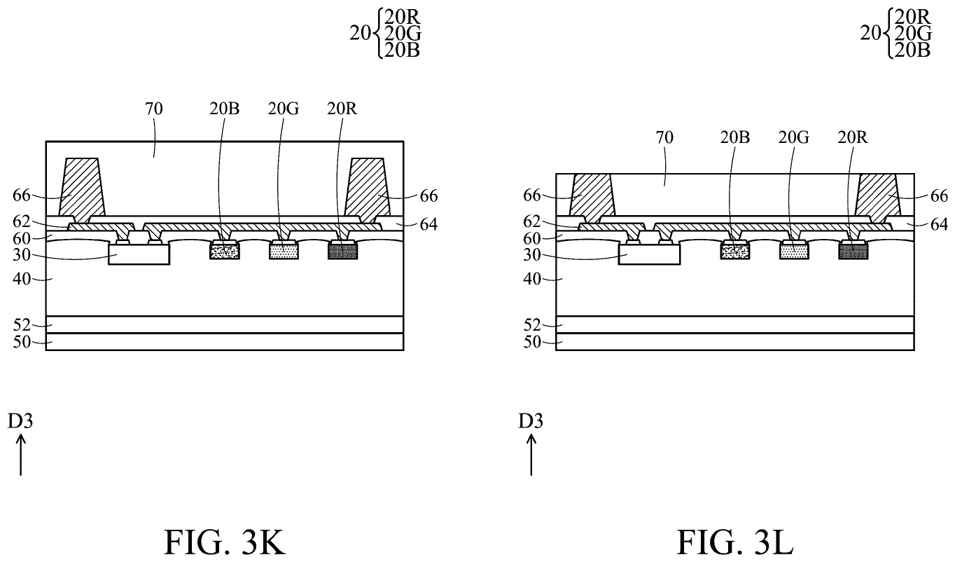

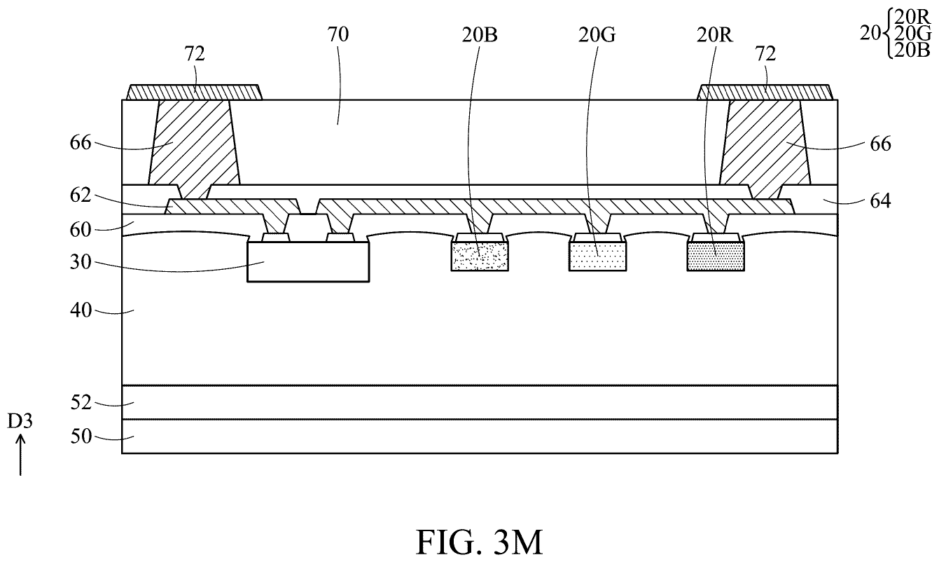

Referring to FIG. 3A to 3M, they are schematic cross-sectional views of different stages of a method for forming a packaging structure 1 according to some embodiments of the present disclosure.

As shown in FIG. 3A, in some embodiments, a substrate 10 may be provided. In some embodiments, the substrate 10 may include silicon, glass, sapphire, ceramic, other suitable substrates, or a combination thereof, but the present disclosure is not limited thereto. In some embodiments, the substrate 10 may include polyimide (PI), polycarbonate (PC), polyethylene terephthalate (PET), polypropylene (PP), other suitable substrates, or a combination thereof, but the present disclosure is not limited thereto. In some embodiments, a first release layer 12 may be formed on the substrate 10.

As shown in FIG. 3B, in some embodiments, a first adhesive layer 14 may be formed on the first release layer 12. In some embodiments, the first release layer 12 may include laser release glue, thermal release glue, ultraviolet release (UV) glue, light-to-heat conversion (LTHC) glue, other suitable materials, or a combination thereof, but the present disclosure is not limited thereto. In some embodiments, the first adhesive layer 14 may be silicone, epoxy, polyimide (PI), polybenzoxazole (PBO), other suitable materials, or a combination thereof, but the present disclosure is not limited thereto. In some embodiments, the first adhesive layer 14 may be formed by a coating process, other suitable formation processes, or a combination thereof, but the present disclosure is not limited thereto. In some embodiments, a mass transfer process may be performed to transfer the plurality of light-emitting elements 20 and the integrated circuit element 30 to the first adhesive layer 14. In some embodiments, the bonding pads 22 of the light-emitting element 20 and the bonding pads 32 of the integrated circuit element 30 may be embedded in the first adhesive layer 14. In some embodiments, due to the mass transfer process, a laser transfer adhesive 34 may be present on the integrated circuit element 30. In some embodiments, the laser transfer adhesive 34 may be silicone, epoxy, polyimide (PI), polybenzoxazole (PBO), other suitable materials, or a combination thereof, but the present disclosure is not limited thereto.

As shown in FIG. 3C, in some embodiments, the first adhesive layer 14 may be partially removed, and the remaining portion of the first adhesive layer 14 may be maintained. Therefore, the shape of the subsequently formed cover layer 40 may be adjusted based on the shape of the remaining portion of the first adhesive layer 14. For example, the remaining portion of the first adhesive layer 14 may have a concave top surface. In some embodiments, the first adhesive layer 14 not covered by the light-emitting elements 20 and the integrated circuit element 30 may be partially removed, and a portion of the first adhesive layer 14 not covered by the light-emitting elements 20 and the integrated circuit element 30 may be maintained. In some embodiments, the first adhesive layer 14 located below the light-emitting elements 20 and the integrated circuit element 30 may be partially retained, and a portion of the first adhesive layer 14 adjacent to the bottoms of the light-emitting element 20 and the integrated circuit element 30 may be removed. In some embodiments, the laser transfer adhesive 34 may be removed to expose the integrated circuit element 30. In some embodiments, the removal of the first adhesive layer 14 and the removal of the laser transfer adhesive 34 may be performed in the same process or in different processes.

As shown in FIG. 3D, in some embodiments, the cover layer 40 may be blanketly formed on the first adhesive layer 14, the light-emitting element 20, and the integrated circuit element 30. Since the cover layer 40 may be in direct contact with the first adhesive layer 14, the shape of the cover layer 40 may correspond to the shape of the first adhesive layer 14. In some embodiments, the cover layer 40 may be formed by a chemical vapor deposition, another suitable formation processes, or a combination thereof. In some embodiments, a carrier 50 may be provided, and a second release layer 52 may be provided on the carrier 50. In some embodiments, the material of the carrier 50 may be the same as or different from the material of the substrate 10, and the material of the second release layer 52 may be the same as or different from the material of the first release layer 12. In some embodiments, the second release layer 52 may be bonded to the cover layer 40 so that the cover layer 40 may be between the second release layer 52 and the first release layer 12.

As shown in FIG. 3E, in some embodiments, the structure shown in FIG. 3D may be turned over (upside down) and the substrate 10 may be removed. In some embodiments, the substrate 10 may be removed by a lift-off process, but the present disclosure is not limited thereto.

As shown in FIG. 3F, in some embodiments, the first release layer 12 and the first adhesive layer 14 may be removed to expose the bonding pads 22 of the light-emitting element 20 and the bonding pads 32 of the integrated circuit element 30. In some embodiments, the first release layer 12 and the first adhesive layer 14 may be removed by a heating process, a light irradiation process, or a combination thereof, but the present disclosure is not limited thereto.

As shown in FIG. 3G, in some embodiments, a first dielectric layer 60 may be formed on the cover layer 40, the integrated circuit element 30, and the light-emitting element 20. In some embodiments, the first dielectric layer 60 may be formed by a chemical vapor deposition, another suitable formation processes, or a combination thereof. In some embodiments, the first dielectric layer 60 may be patterned to form a first opening 61 in the first dielectric layer 60.

As shown in FIG. 3H, in some embodiments, the redistribution structure 62 may be formed on the first dielectric layer 60 and in the first opening 61. In some embodiments, the redistribution structure 62 may fill the first opening 61 and may be electrically connected to the bonding pad 32 of the integrated circuit element 30 and the bonding pad 22 of the light-emitting element 20. In some embodiments, the redistribution structure 62 may be formed by a electroplating, a chemical vapor deposition, a sputtering, a resistance heating evaporation, an electron beam evaporation, an atomic layer deposition (ALD), another suitable formation processes, or a combination thereof, but the present disclosure is not limited thereto.

As shown in FIG. 3I, in some embodiments, the second dielectric layer 64 may be formed on the first dielectric layer 60 and the redistribution structure 62. In some embodiments, the second dielectric layer 64 may be formed by a chemical vapor deposition, another suitable formation processes, or a combination thereof. In some embodiments, the second dielectric layer 64 may be patterned to form a second opening 65 in the second dielectric layer 64.

As shown in FIG. 3J, in some embodiments, the metal pillar 66 may be formed on the second dielectric layer 64 and in the second opening 65. In some embodiments, the metal pillar 66 may be electrically connected to the redistribution structure 62. In some embodiments, the metal pillar 66 may be formed by an electroplating.

As shown in FIG. 3K, in some embodiments, the packaging layer 70 may be blanketly formed on the second dielectric layer 64 and the metal pillars 66. In some embodiments, the packaging layer 70 may be formed by a chemical vapor deposition, another suitable formation processes, or a combination thereof.

As shown in FIG. 3L, in some embodiments, a planarization process may be performed to make a top surface of the metal pillar 66 aligned with a top surface of the packaging layer 70. In some embodiments, the planarization process may be a chemical mechanical polishing process, but the present disclosure is not limited thereto.

As shown in FIG. 3M, in some embodiments, the bonding pad 72 may be formed on the exposed surface of the metal pillar 66 so that the bonding pad 72 may be electrically connected to the metal pillar 66. In some embodiments, the carrier 50 and the second release layer 52 may be removed. In some embodiments, after the carrier 50 and the second release layer 52 are removed, a cutting process (not shown) may be further performed. Therefore, the packaging structure 1 shown in FIG. 1A may be obtained.

Referring to FIG. 4 and FIG. 5, they are scanning electron microscope (SEM) analysis diagrams of the packaging structure according to some embodiments of the present disclosure, respectively. Among them, FIG. 4 shows a FIB analysis diagram of a cross-sectional view taken along line segment II-II′ of FIG. 2, and FIG. 5 shows a FIB analysis diagram of a cross-sectional view taken along line segment III-III′ of FIG. 2. For ease of explanation, the components around the light-emitting element 20 are shown, but the present disclosure is not limited thereto. The arrangement of the components around the integrated circuit element 30 is similar to the arrangement of the components around the light-emitting element 20.

As shown in FIG. 1A, FIG. 1B, FIG. 4, and FIG. 5, in some embodiments, in the cross-sectional view, the protruding portion 40P of the cover layer 40 may have a triangular profile PRO1. It should be noted that the dotted profile shown in the drawing is only for illustration. In some embodiments, adjacent to the bottom surface 20BS of the light-emitting element 20, the cover layer 40 disposed on the first dielectric layer 60 may be in triangular-like shape. In some embodiments (not shown), adjacent to the bottom surface 30BS of the integrated circuit element 30, the cover layer 40 disposed on the first dielectric layer 60 may be in triangular-like shape.

As shown in FIGS. 4 and 5, in some embodiments, the first dielectric layer 60 may be disposed between the bonding pads 22 of the plurality of light-emitting elements 20 and the cover layer 40. As shown in FIG. 4, the first dielectric layer 60 may be disposed between the bonding pads 22R1 of the red light-emitting element 20R and the cover layer 40. As shown in FIG. 5, the first dielectric layer 60 may be disposed between the bonding pads 22R2 of the red light-emitting element 20R and the cover layer 40. As shown in FIGS. 4 and 5, in some embodiments, the triangular-like profile PRO1 of the cover layer 40 may be in contact with the first dielectric layer 60, and the first dielectric layer 60 may cover a side surface 22SS of the bonding pad 22 away from a center (or a symmetry axis) of the light-emitting element 20. In some embodiments (not shown), the first dielectric layer 60 may be disposed between the bonding pads 32 of the integrated circuit element 30 and the cover layer 40.

As shown in FIGS. 4 and 5, in some embodiments, the first dielectric layer 60 between the bonding pads 22 of the plurality of light-emitting elements 20 and the redistribution structure 62 may have a trapezoidal-like profile PRO2. In some embodiments, the first dielectric layer 60 has a thickness, and the thickness of the trapezoidal-like profile PRO2 of the first dielectric layer 60 gradually decreases in the direction toward the bonding pads 22 of the plurality of light-emitting elements 20. In some embodiments, the trapezoidal-like profile PRO2 of the first dielectric layer 60 has a side edge E3 and a bottom edge E4, and the angle between the side edge E3 and the bottom edge E4 may be greater than or equal to 20 degrees and less than or equal to 50 degrees. For example, the angle between the side edge E3 and the bottom edge E4 may be 20 degrees, 25 degrees, 30 degrees, 35 degrees, 40 degrees, 45 degrees, 50 degrees, or any value or any range of values between the aforementioned values, but the present disclosure is not limited thereto. In some embodiments, the first dielectric layer 60 may have a tip end (tapered end) between the bonding pad 22 and the redistribution structure 62, and the tip end toward a center (or a symmetry axis) of the light-emitting element 20. In some embodiments (not shown), the first dielectric layer 60 may have a trapezoidal-like profile between the bonding pad 32 of the integrated circuit element 30 and the redistribution structure 62.

As shown in FIGS. 4 and 5, in some embodiments, the first dielectric layer 60 may cover the bottom surface 22BS and the side surface 22SS of the bonding pads 22 of the plurality of light-emitting elements 20. In some embodiments, the first dielectric layer 60 may cover a portion of the bottom surface 22BS of the bonding pads 22, and the first dielectric layer 60 may cover the side surface 22SS of the bonding pads 22 away from a center (or a symmetry axis) of the light-emitting element 20. In some embodiments (not shown), the first dielectric layer 60 may cover the bottom surface 32BS and the side surface of the bonding pads 32 of the integrated circuit element 30.

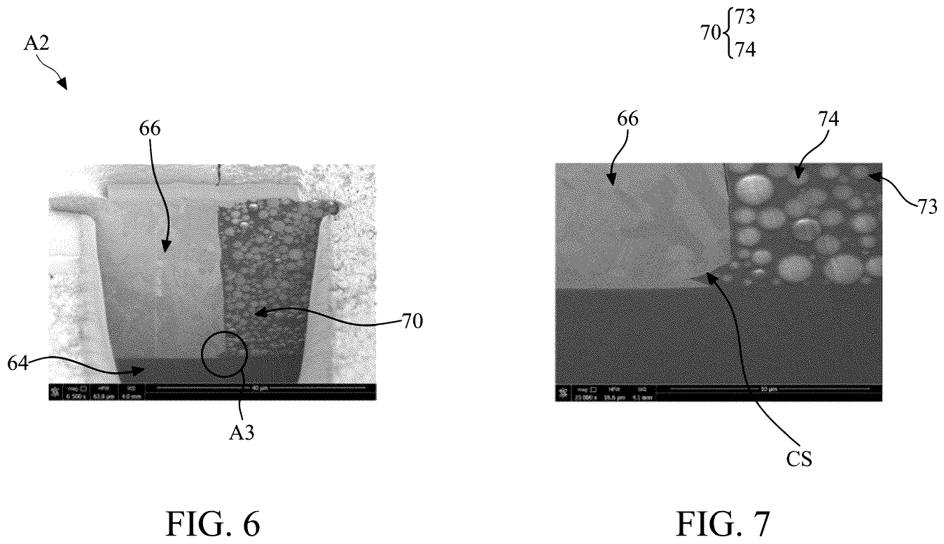

Referring to FIGS. 6 and 7, they are scanning electron microscope (SEM) analysis diagrams of a packaging structure according to some embodiments of the present disclosure, respectively. Among them, FIG. 6 shows a schematic enlarged view of the second area A2 in FIG. 1A, and FIG. 7 shows a schematic enlarged view of the third area A3 in FIG. 6.

As shown in FIGS. 6 and 7, in some embodiments, the metal pillar 66 adjacent to the second dielectric layer 64 may have a concave structure CS, and the packaging layer 70 may surround the metal pillar 66 and fill the concave structure CS of the metal pillar 66. In some embodiments, the concave structure CS may be located on opposite sides of the metal pillar 66 (not shown), and the packaging layer 70 may fill the concave structure CS located on both sides of the metal pillar 66. In some embodiments, the concave structure CS may be annularly disposed at the periphery of the metal pillar 66, and the packaging layer 70 may fill the concave structure CS located at the periphery of the metal pillar 66.

In some embodiments, the concave structure CS may be a tip gradually formed from the edge of the metal pillar 66 to the inside of the metal pillar 66. In some embodiments, in the schematic cross-sectional view, the concave structure CS may have pointed cone shape. In some embodiments, the packaging layer 70 may include a molding material 73 (for example, the dark part in FIG. 7) and diffusion particles (filler) 74 (for example, the light part in FIG. 7). In some embodiments, the diffusion particles 74 may include titanium dioxide (TiO₂), silicon dioxide (SiO₂), boron oxide (BN), aluminum oxide (Al₂O₃), or zirconium dioxide (ZrO₂). In some embodiments, the diffusion particles 74 may include hollow silicon dioxide (SiO₂) or solid silicon dioxide (SiO₂).

In some embodiments, the concave structure CS may be a structure generated by the interface between the seed layer (not shown) used to form the metal pillar 66 and the metal pillar 66 itself, but the present disclosure is not limited thereto. The concave structure CS may improve the adhesion between the metal pillar 66 and the packaging layer 70 (for example, increase the contact area). Accordingly, by filling the packaging layer 70 in the concave structure CS of the metal pillar 66, the bonding reliability of the packaging structure 1 may be increased.

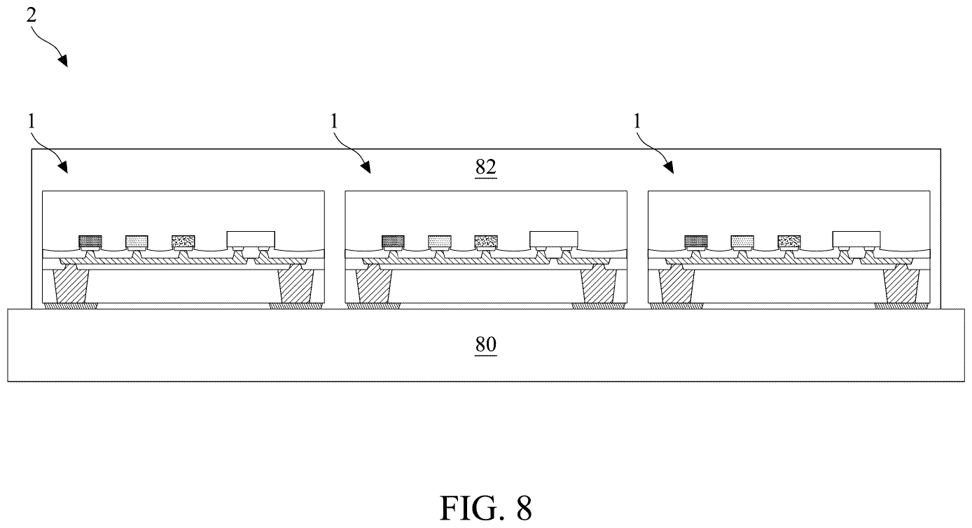

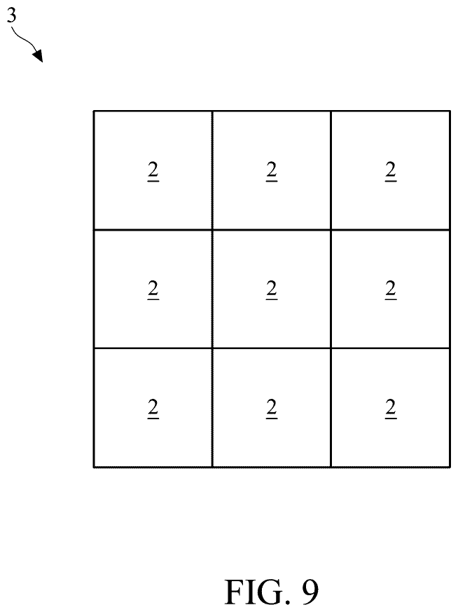

Referring to FIG. 8, it is a schematic cross-sectional view of a display device according to some embodiments of the present disclosure. In some embodiments, the display device 2 may include one or more packaging structures 1. In some embodiments, the display device 2 may further include an additional conductive layer, an additional insulating layer, an additional element, or a combination thereof, but the present disclosure is not limited thereto. Among them, the packaging structure 1 may be used as a pixel unit and applied to the display device 2. In some embodiments, the number of packaging structures 1 in the display device 2 may be 1 to 10,000. For ease of explanation, three packaging structures 1 are shown in FIG. 8, but the present disclosure is not limited thereto. In some embodiments, the display device 2 may include a circuit board 80, and the packaging structure 1 may be disposed on the circuit board 80. For example, the circuit board 80 may be a printed circuit board (PCB). In some embodiments, the packaging structure 1 and the circuit board 80 may be electrically connected by a bonding material. In some embodiments, the display device 2 may include a packaging material 82, and the packaging material 82 may cover the top surface and side surface of the packaging structure 1 and the top surface of the circuit board 80.

Referring to FIG. 9, it is a schematic top view of a spliced display device 3 according to some embodiments of the present disclosure. In some embodiments, the spliced display device 3 may include a plurality of display devices 2. In some embodiments, the number of display devices 2 in the spliced display device 3 may be 1 to 10,000. For ease of description, nine display devices 2 are shown in FIG. 9, but the present disclosure is not limited thereto.

In some embodiments, the packaging structure and the display device including the packaging structure disclosed herein may be used in applications requiring high light-emitting (luminous) efficiency and high brightness.

Accordingly, the present disclosure uses a redistribution last (RDL last) process to extend electrodes of the light-emitting elements and integrated circuit element in the packaging structure to form bonding pads (for example, bonding pads 72) that electrically connect the packaging structure to the outside. Therefore, the present disclosure may improve light-emitting efficiency, improve bonding reliability, and/or avoid electrical failure.

The components of the embodiments disclosed herein may be mixed and combined as desired as long as they do not violate the spirit of the disclosure or conflict with each other. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A packaging structure, comprising:
a first dielectric layer, wherein the first dielectric layer has a top surface and a side surface;
a redistribution structure disposed in the first dielectric layer;
a plurality of light-emitting elements disposed on the first dielectric layer;
an integrated circuit element disposed on the first dielectric layer and adjacent to the plurality of light-emitting elements; and
a cover layer surrounding the plurality of light-emitting elements and the integrated circuit element and in direct contact with the top surface and the side surface of the first dielectric layer.

2. The packaging structure as claimed in claim 1, wherein the cover layer surrounds the redistribution structure.

3. The packaging structure as claimed in claim 1, wherein the plurality of light-emitting elements has a bottom surface, the integrated circuit element has a bottom surface, the cover layer has a protruding portion, and the protruding portion covers the bottom surface of the plurality of light-emitting elements and the bottom surface of the integrated circuit element.

4. The packaging structure as claimed in claim 3, wherein in a cross-sectional view, the protruding portion of the cover layer has a triangular-like profile.

5. The packaging structure as claimed in claim 4, wherein a vertex of the triangular-like profile is located below the bottom surface of the plurality of light-emitting elements or below the bottom surface of the integrated circuit element.

6. The packaging structure as claimed in claim 1, wherein the plurality of light-emitting elements has a bonding pad, and the bonding pad is electrically connected to the redistribution structure.

7. The packaging structure as claimed in claim 6, wherein the first dielectric layer between the bonding pad of the plurality of light-emitting elements and the redistribution structure has a trapezoidal-like profile.

8. The packaging structure as claimed in claim 7, wherein the trapezoidal-like profile has a height, and the height decreases toward the bonding pad of the plurality of light-emitting elements.

9. The packaging structure as claimed in claim 7, wherein the trapezoidal-like profile has a side edge and a bottom edge, and an angle between the side edge and the bottom edge is greater than or equal to 20 degrees and less than or equal to 50 degrees.

10. The packaging structure as claimed in claim 6, wherein the bonding pad has a bottom surface and a side surface, and the first dielectric layer covers the bottom surface and the side surface of the bonding pad of the plurality of light-emitting elements.

11. The packaging structure as claimed in claim 6, wherein the first dielectric layer is disposed between the bonding pad of the plurality of light-emitting elements and the cover layer.

12. The packaging structure as claimed in claim 1, wherein the cover layer has a bottom surface between two adjacent light-emitting elements of the plurality of light-emitting elements and protruding toward the first dielectric layer.

13. The packaging structure as claimed in claim 1, wherein the cover layer has a bottom surface between one of the plurality of light-emitting elements and the integrated circuit element and protruding toward the first dielectric layer.

14. The packaging structure as claimed in claim 1, wherein a top surface of the plurality of light-emitting elements is a light-emitting surface, and the cover layer is in direct contact with the top surface of the plurality of light-emitting elements.

15. The packaging structure as claimed in claim 14, wherein a top surface of the integrated circuit element is higher than the top surface of the plurality of light-emitting elements.

16. The packaging structure as claimed in claim 1, wherein the first dielectric layer has a neck portion surrounding the redistribution structure.

17. The packaging structure as claimed in claim 1, wherein the plurality of light-emitting elements is arranged along a side of the integrated circuit element.

18. The packaging structure as claimed in claim 1, wherein the redistribution structure is electrically connected to the plurality of light-emitting elements and the integrated circuit element.

19. The packaging structure as claimed in claim 1, further comprising:
a second dielectric layer disposed on the redistribution structure, wherein the redistribution structure is between the first dielectric layer and the second dielectric layer,
wherein the first dielectric layer and the second dielectric layer surround the redistribution structure.

20. The packaging structure as claimed in claim 19, further comprising:
a packaging layer disposed on the second dielectric layer, wherein the second dielectric layer is between the redistribution structure and the packaging layer;
a metal pillar disposed in the packaging layer and electrically connected to the redistribution structure; and
a bonding pad disposed on the packaging layer and electrically connected to the metal pillar.
